(19) United States
(12) Patent Application Publication
(10) Pub. No.: US 2008/0042198 A1
(43) Pub. Date: Feb. 21, 2008

(54) DEMOS STRUCTURE

(76) Inventor: Chul-Jin Yoon, Seoul (KR)

Correspondence Address: SHERR & NOURSE, PLLC, 620 HERNDON PARKWAY, SUITE 200, HERNDON, VA, 20170, US

(21) Appl. No.: 11/840,083

(22) Filed: Aug. 16, 2007

(30) Foreign Application Priority Data
Aug. 17, 2006 (KR) 10-2006-0077611

(51) Int. Cl. H01L 29/78; H01L 21/336

(52) U.S. Cl. 257/344; 438/286; 257/E29.268; 257/E21.427

(57) ABSTRACT

Embodiments relate to a Drain Extended Metal-Oxide-Semiconductor (DEMOS) structure in which a drain region may be longer than a source region. In embodiments, the DEMOS may include a gate insulating film and a gate electrode sequentially layered over a semiconductor substrate, a spacer formed at a sidewall of a gate electrode toward the source region, an insulating film pattern formed at a sidewall of the gate electrode toward the drain region to provide a great spacing between the gate electrode and the drain region, the source region formed in the substrate to be in alignment with an edge of the spacer, and the drain region formed in the substrate to be in alignment with an edge of the insulating film pattern. The spacer and the insulating film pattern may be silicon oxide films.

The present application claims priority under 35 U.S.C. 119 and 35 U.S.C. 365 to Korean Patent Application No. 10-2006-0077611 (filed on Aug. 17, 2006), which is hereby incorporated by reference in its entirety.

### BACKGROUND

High integration of a semiconductor device may result in a reduction of a Critical Dimension (CD) of a gate of a MOS transistor. Various technologies for providing a solution to such a reduction have been proposed. Among proposed technologies, a Drain Extended Metal Oxide Semiconductor (DEMOS) device, which may have a drain that is greater in length than a source, may be used.

FIG. 1 a cross-sectional diagram illustrating a related art DEMOS structure.

Referring to FIG. 1, in the related art DEMOS structure, gate insulating film 16 and gate electrode 18 may be sequentially formed over a silicon substrate that may be semiconductor substrate 10. Lightly Doped Drain (LDD) region 22, which may be implanted with impurities to a shallow depth in the substrate, may be formed and may be in alignment with an edge of gate electrode 18. Spacer 24 may be formed at a sidewall of gate electrode 18.

Source region 28a may be formed in the substrate and may be aligned with an edge of spacer 24. Drain region 28b may be formed in the substrate at a prescribed distance from spacer 24. Drain region 28b may be shaped to have a greater length than source region 28a.

Surface oxidation film 20 may be formed on a top and a side surface of gate electrode 18. Insulating film pattern 30 may be formed and may cover part of a top of gate electrode 18 toward the drain region 28b, spacer 24 on a side of drain region 28b, and part of drain region 28b. Silicide film 32 may be formed on a surface of source/drain region 28a/28b.

FIGS. 2A to 2H are diagrams illustrating a procedure for manufacturing a related art DEMOS.

Referring to FIGS. 2A to 2H, a procedure for manufacturing a related art DEMOS may be based on an example of an NMOS structure.

Referring to FIG. 2A, buffer oxide film 12 may be formed on a silicon substrate that is semiconductor substrate 10. P-type impurities (e.g., boron (B)) may be implanted and P-type well 14 may be formed in semiconductor substrate 10 including buffer oxide film 12.

Referring to FIG. 2B, buffer oxide film 12 may be removed in a wet etching process. Silicon oxide film (SiO₂) 16 may be formed as a gate insulating film over semiconductor substrate 10.

A doped polysilicon film, which may be a conductive film for gate electrode, may be deposited on gate insulating film 16. The doped polysilicon film may be patterned in a photolithography process using a gate mask, thereby forming gate electrode 18.

An oxidation process may be performed and surface oxidation film 20 may be formed on a top and a side surface of gate electrode 18.

Referring to FIG. 2C, N-type impurities (e.g., phosphorous (P) or arsenic (As)) may be implanted and shallow LDD region 22 may be formed in semiconductor substrate 10.

Referring to FIG. 2D, a silicon nitride film (Si₃N₄), which may be an insulating film, may be deposited over a whole surface of semiconductor substrate 10. The silicon nitride film may be etched in a dry etching process, for example, a Reactive Ion Etching (RIE) process, and may form spacers 24 at a sidewalls of gate electrode 18.

Referring to FIG. 2E, a photolithography process may be performed using a mask defining a drain region 28b of the DEMOS. Photoresist pattern 26 may thus be formed and may cover part of a top of gate electrode 18, spacer 24 provided at a side surface thereof, and part of LDD region 22.

N-type impurities (e.g., P or As) may be implanted with spacer 24 and photoresist pattern 26 as masks. Source/drain region 28a/28b may be formed at a deep depth. Source region 28a may be formed within P-type well 14 and may be aligned with an edge of spacer 24. The drain region 28b may be aligned with an edge of photoresist pattern 26 and may be formed within P-type well 14 to be at a distance from spacer 24. Drain region 28b may be shaped to have a greater length than source region 28a.

Referring to FIG. 2F, an ashing process may be performed and photoresist pattern 26 may be removed.

Referring to FIG. 2G, a silicon oxide film (SiO₂), which may be an insulating film, may be deposited. The silicon oxide film may be patterned in a photolithography process and insulating film pattern 30 may be formed to cover part of a top of gate electrode 18, spacer 24 provided on a side surface thereof, and part of the drain region 28b.

Referring to FIG. 2H, titanium (Ti) may be deposited as metal silicide material over a surface, for example an entire surface, of the substrate. An annealing process may be performed for silicide reaction between titanium and silicon of source/drain region 28a/28b. Thus, silicide film 32 may be formed on a surface of source/drain region 28a/28b. Metal non-silicide material may be removed in a rinsing process.

A related art procedure for manufacturing a DEMOS may provide a MOS having a drain region that may be greater in length than the source region. This may reduce a breakdown voltage of a highly integrated semiconductor device.

However, the related art DEMOS manufacturing procedure may be disadvantageous with respect to the level of difficulty and an increase in a number of manufacturing steps necessary since it may require a spacer manufacturing process, a source/drain ion-implantation process, an insulating film pattern manufacturing process, etc. to be performed separately.

### SUMMARY

Embodiments relate to a Metal Oxide Semiconductor (MOS) transistor and a method for manufacturing the same, and to a Drain Extended MOS (DEMOS) structure and a method for manufacturing the same, that may simplify a process of manufacturing a DEMOS used in a power semiconductor device chip.

Embodiments relate to a DEMOS structure and a method for manufacturing the same, which may include a spacer formed at a sidewall of a gate electrode toward a source region and an insulating film pattern providing a great spacing between the gate electrode and a drain region formed at a sidewall of the gate electrode toward the drain region, which may reduce a total manufacturing process. In embodiments, the two spacers may be formed at the same time.

According to embodiments, a Drain Extended Metal-Oxide-Semiconductor (DEMOS) structure in which a drain region is longer than a source region may include a gate insulating film and a gate electrode sequentially layered over a semiconductor substrate, a spacer formed at a sidewall of a gate electrode toward the source region, an insulating film pattern formed at a sidewall of the gate electrode toward the drain region to provide a first spacing between the gate electrode and the drain region, the source region formed in the substrate to be in alignment with an edge of the spacer, and the drain region formed in the substrate to be in alignment with an edge of the insulating film pattern. The first spacing between the gate electrode and the drain region may be greater than a spacing between the gate electrode and the source region.

According to embodiments, a method for manufacturing a DEMOS whose drain region is longer than a source region may include sequentially forming a gate insulating film and a gate electrode over a semiconductor substrate, forming a spacer at a sidewall of a gate electrode toward the source region and at the same time, forming an insulating film pattern at a sidewall of the gate electrode toward the drain region to provide a great spacing between the gate electrode and the drain region, and forming the source region in the substrate to be in alignment with an edge of the spacer and at the same time, forming the drain region in the substrate to be in alignment with an edge of the insulating film.

### DRAWINGS

FIG. 1 is a cross-sectional diagram illustrating a related art DEMOS structure.

FIGS. 2A to 2H are process diagrams illustrating a related art procedure for manufacturing a DEMOS.

FIG. 3 is a cross-sectional diagram illustrating a DEMOS structure according to embodiments.

FIGS. 4A to 4H are process diagrams illustrating a procedure for manufacturing a DEMOS structure according to embodiments.

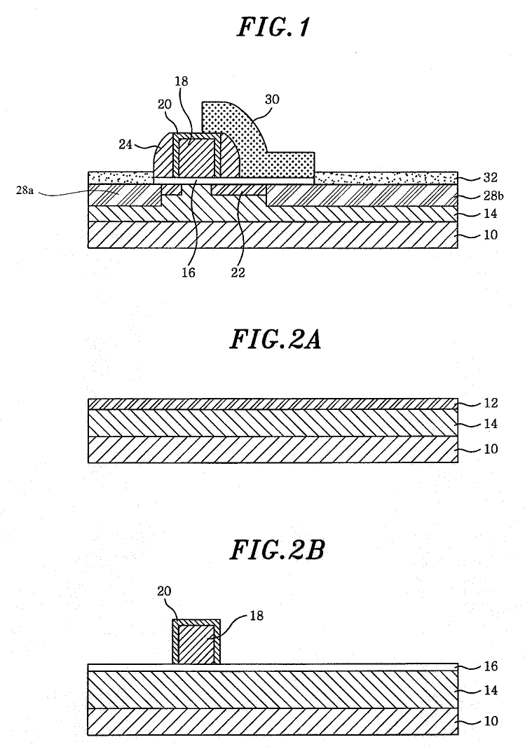

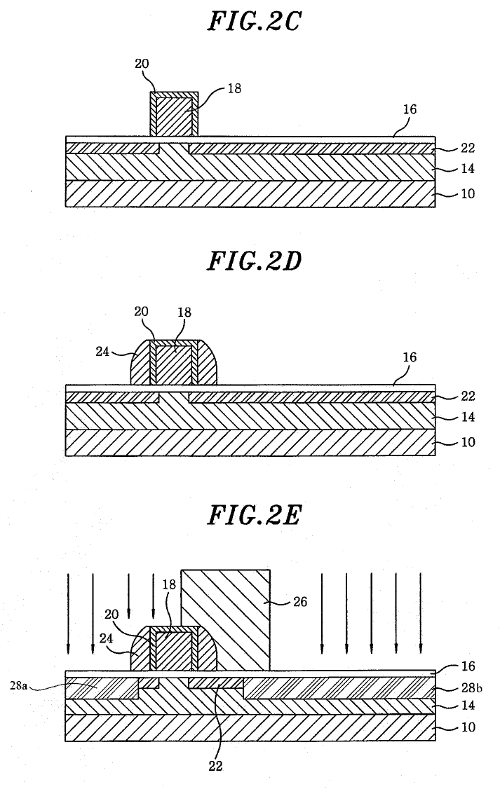

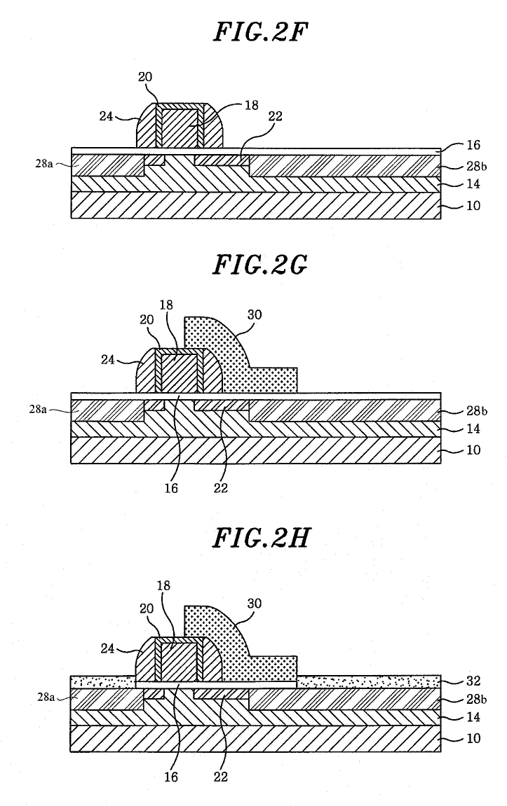

### DETAILED DESCRIPTION

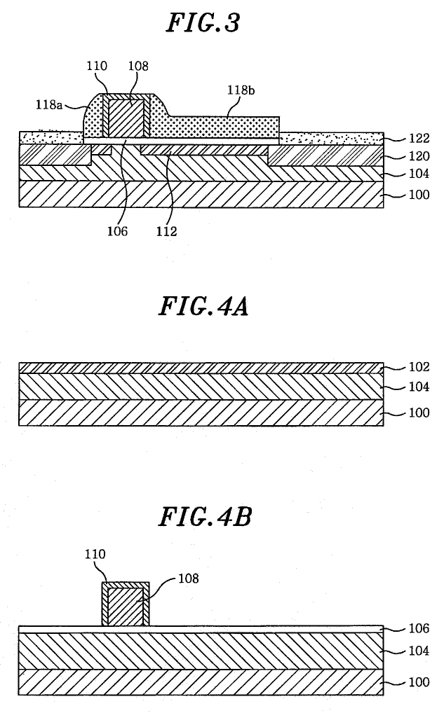

Referring to FIG. 3, in a DEMOS structure according to embodiments, gate insulating film 106 and gate electrode 108 may be sequentially formed over a silicon substrate, which may be semiconductor substrate 100. LDD region 112, which may be implanted with impurities to a shallow depth in the substrate, may be formed and may be in alignment with an edge of gate electrode 108.

Spacer 118a may be formed by a predetermined thickness, for example, a thickness of 1000 Å, at a sidewall of gate electrode 108 toward a source region. Insulating film pattern 118b, which may provide a relatively big spacing between gate electrode 108 and drain region 120b, may be formed at a sidewall of gate electrode 108 toward drain region 120b.

Source region 120a may be formed in the substrate and may be in alignment with an edge of spacer 118a. Drain region 120b may be formed in the substrate and may be in alignment with an edge of insulating film pattern 118b. Drain region 120b may be shaped to have a greater length than source region 120a.

Silicide film 122 may be formed on a surface of source/drain region 120a/120b.

According to embodiments, a DEMOS may include spacer 118a and insulating film pattern 118b that may be formed together, and not formed separately. This may be because spacer 118a may be formed at the sidewall of gate electrode 108 toward the source region, and insulating film pattern 118b, which may provide a substantial spacing between gate electrode 108 and drain region 120b, may be formed at the sidewall of gate electrode 108 toward drain region 120b.

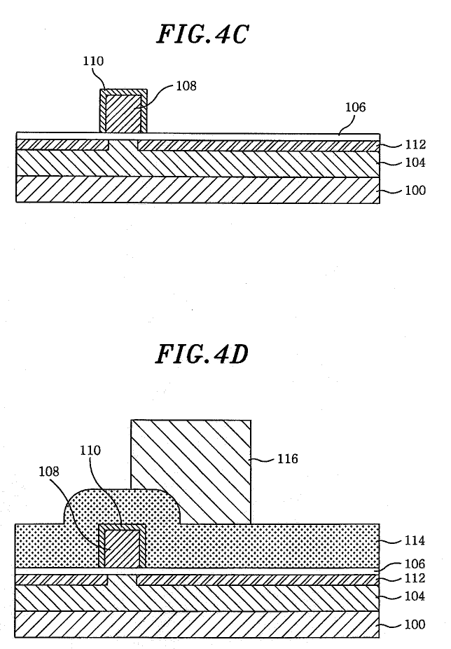

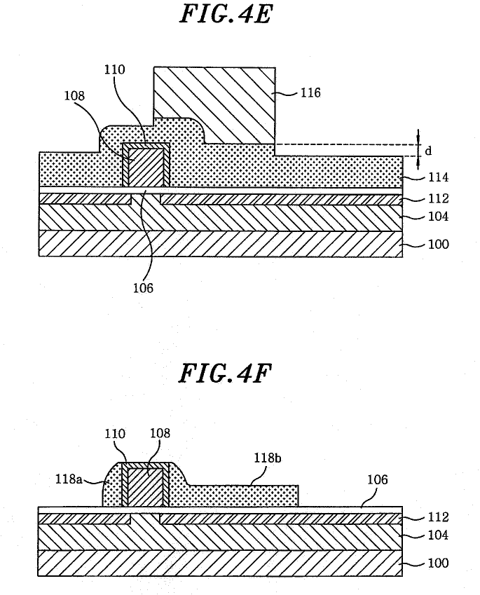

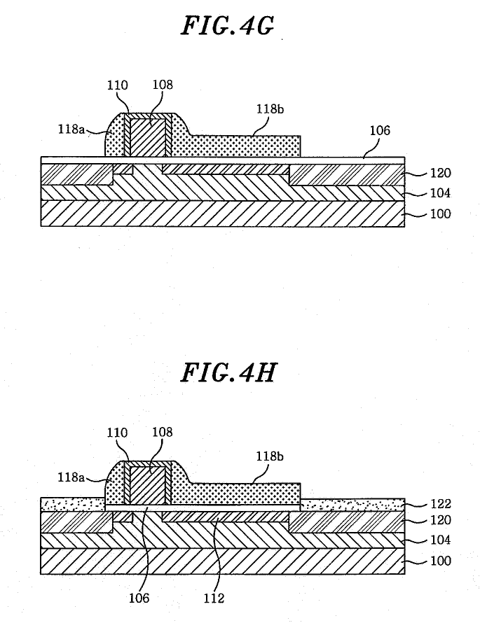

Referring to FIGS. 4A to 4H, a procedure for manufacturing a DEMOS according to embodiments will be described. The DEMOS manufacturing procedure may be based on an example of an NMOS structure.

Referring to FIG. 4A, buffer oxide film 102 may be formed on a silicon substrate, which may be semiconductor substrate 100. P-type impurities (e.g., boron (B)) may be implanted and P-type well 104 may be formed in semiconductor substrate 100 including buffer oxide film 102.

Referring to FIG. 4B, buffer oxide film 102 may be removed, for example by a wet etching process. Silicon oxide film (SiO₂) 106 may be formed as a gate insulating film over semiconductor substrate 100.

A doped polysilicon film that may be a conductive film for gate electrode may be deposited on gate insulating film 106. The doped polysilicon film may be patterned, for example in a photolithography process using a gate mask, and may form gate electrode 108.

In embodiments, an oxidation process may then be performed and surface oxidation film 110 may be formed on a top and a side surface of gate electrode 108.

Referring to FIG. 4C, N-type impurities (e.g., phosphorous (P) or arsenic (As)) may be implanted and shallow LDD region 112 may be formed in semiconductor substrate 100.

Referring to FIG. 4D, a silicon oxide film (SiO₂), which may be insulating film 114, may be deposited on a surface, for example an entire surface, of semiconductor substrate 100. In embodiments, silicon oxide film 114 may have a thickness considering a remainder of subsequently formed spacer 118a, and in embodiments a thickness may be 1500 Å.

A photolithography process may be performed at a top of insulating film 114, and may use a mask defining a drain region of DEMOS. In embodiments, photoresist pattern 116 may thus be formed to cover part of a top of gate electrode 108, a side surface thereof, and part of LDD region 112 toward drain 120b.

Referring to FIG. 4E, the silicon oxide film that is insulating film 114, which may be exposed by photoresist pattern 116, may be dry etched by predetermined thickness (d). In embodiments, thickness (d) may be set as a remaining thickness (e.g., 500 Å) excepting a thickness (e.g., 1000 Å) of spacer 118a from a total thickness (e.g., 1500 Å) of insulating film 114.

In embodiments, an ashing process may be performed and photoresist pattern 116 may be removed.

Referring to FIG. 4F, a dry etching process, for example, a blanket etching process, may be performed using gas such as CH₄. In embodiments, spacer 118a may thus be formed at a sidewall of gate electrode 108 toward source region 120a and at the same time, insulating film pattern 118b providing a relatively large spacing between gate electrode 108 and drain region 120b may be formed at a sidewall of gate electrode 108 toward drain region 120b.

Referring to FIG. 4G, N-type impurities (e.g., P or As) may be implanted with spacer 118a and insulating film pattern 118b as masks and source/drain region 120a/120b may be formed at a relatively large depth. The source region may be formed within P-type well 104 and may be in alignment with an edge of spacer 118a. The drain region may be formed within P-type well 104 and may be in alignment with an edge of insulating film pattern 118b. Drain region 120b may be shaped to have a greater length than source region 120a.

Referring to FIG. 4H, titanium (Ti) may be deposited as metal silicide material over a surface, for example an entire surface, of the substrate. In embodiments, an annealing process may be performed to generate a silicide reaction between titanium and silicon of source/drain region 120a/120b. In embodiments, silicide film 122 may thus be formed on a surface of source/drain region 120a/120b. Metal non-silicide material may be removed in a rinsing process.

According to embodiments, in a procedure for manufacturing a DEMOS, spacer 118a may be formed at the sidewall of gate electrode 108 toward source region 120a. At the same time, insulating film pattern 118b, which may provide a relatively large spacing between gate electrode 108 and drain region 120b, may be formed at a sidewall of gate electrode 108 toward drain region 120b. According to embodiments, spacer 118a and insulating film pattern 118b may be formed simultaneously, not separately, which may reduce a total manufacturing process.

As described above, in embodiments, in the procedure for manufacturing the DEMOS which may have a drain that is longer than a source, the spacer may be formed at the sidewall of the gate electrode toward the source region and at the same time, the insulating film pattern providing the great spacing between the gate electrode and the drain region may be formed at the sidewall of the gate electrode toward the drain region. By doing so, the spacer and the insulating film pattern may be formed simultaneously, not separately, unlike the related art. This may provide an advantage by reducing a total manufacturing process.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A Drain Extended Metal-Oxide-Semiconductor (DEMOS) structure, comprising:
a gate insulating film and a gate electrode layered over a semiconductor substrate;
a source region formed in the substrate;
a drain region formed in the substrate;
a spacer having a first width formed at a first sidewall of the gate electrode adjacent to the source region; and
an insulating film pattern having a second width greater than the first width formed at a second sidewall of the gate electrode and extending over the semiconductor substrate toward the drain region, wherein the source region formed in the substrate is substantially aligned with an outer edge of the spacer and the drain region formed in the substrate is substantially aligned with an outer edge of the insulating film pattern.

2. The structure of claim 1, wherein a distance between the gate electrode and the drain region is greater than a distance between the gate electrode and the source region.

3. The structure of claim 2, wherein a width of the drain region is substantially greater than a width of the source region.

4. The structure of claim 1, wherein the spacer and the insulating film pattern comprise silicon oxide films.

5. The structure of claim 1, further comprising a Lightly Doped Drain (LDD) region formed in the substrate and substantially in alignment with an edge of the gate electrode.

6. The structure of claim 1, wherein the spacer and the insulating film pattern are formed simultaneously.

7. The structure of claim 1, wherein a width of the insulating film pattern controls a distance between the gate region and the drain region.

8. A method for manufacturing a Drain Extended Metal-Oxide-Semiconductor (DEMOS), comprising:
forming a gate insulating film and a gate electrode over a semiconductor substrate;
simultaneously forming a spacer at a sidewall of a gate electrode on a side of a source region and an insulating film pattern at a sidewall of the gate electrode on a side of a drain region; and
simultaneously forming the source region in the substrate to be substantially in alignment with an edge of the spacer and the drain region in the substrate to be substantially in alignment with an edge of the insulating film, wherein more spacing is provided between the gate electrode and the drain region than between the gate electrode and the source region.

9. The method of claim 8, wherein the spacer and the insulating film pattern comprise silicon oxide.

10. The method of claim 8, wherein forming the spacer and the insulating film pattern comprises:
forming an insulating film over a surface of the substrate comprising the gate electrode;
forming a photoresist pattern defining the drain region of the DEMOS over the insulating film;
etching the insulating film by a prescribed thickness;
removing the photoresist pattern; and
dry etching the insulating film to form the spacer and the insulating film pattern.

11. The method of claim 10, wherein the spacer and the insulating film pattern comprise silicon oxide.

12. The method of claim 8, further comprising forming an LDD region in the substrate substantially in alignment with an edge of the gate electrode after forming the gate electrode.

13. A device, comprising:
a substrate;
a source region formed in the substrate;
a drain region formed in the substrate;
a gate region formed over the substrate;
a spacer formed over the source region and contacting a first side of the gate region, the first side being located on a side of the source region;
an insulating film pattern formed over the drain region and contacting a second side of the gate region, the second side being located on a side of the drain region.

14. The device of claim 13, wherein the gate region is isolated from the drain region by the insulating film pattern.

15. The device of claim 13, wherein a width of the drain region is greater than a width of the source region.

16. The device of claim 15, wherein a distance between the gate electrode and the drain region is greater than a distance between the gate electrode and the source region.

17. The device of claim 16, wherein the spacer and the insulating film pattern are formed simultaneously.

18. The device of claim 17, wherein a size and location of the insulating film pattern controls a distance between the gate and the drain region.

19. The device of claim 18, wherein the source and drain regions are formed simultaneously.

20. The device of claim 19, wherein the source region is substantially aligned with an edge of the spacer and the drain region is substantially aligned with an edge of the insulating film pattern.
